(19) United States
(12) Patent Application Publication
(10) Pub. No.: US 2015/0076629 A1
(43) Pub. Date: Mar. 19, 2015

(54) MICROPHONE

(71) Applicant: Samsung Electro-Mechanics Co., Ltd., Suwon (KR)

(72) Inventors: Hwa Sun LEE, Suwon (KR); Byung Hun Kim, Suwon (KR); Yoon Sok Park, Suwon (KR)

(73) Assignee: Samsung Electro-Mechanics Co., Ltd., Suwon (KR)

(21) Appl. No.: 14/081,058

(22) Filed: Nov. 15, 2013

(30) Foreign Application Priority Data
Sep. 17, 2013 (KR) 10-2013-0111703

(51) Int. Cl. B81B 3/00

(52) U.S. Cl. CPC B81B 3/0021
USPC 257/416

(57) ABSTRACT

There is provided a microphone including: a thin film member including leg members extended in a direction not in parallel with a vibration direction; first supports supporting first points of the leg members, respectively; and a piezoelectric member connected to second points of the leg members and converting vibrations of the thin film member into electrical signals.

### CROSS-REFERENCE TO RELATED APPLICATION

This application claims the benefit of Korean Patent Application No. 10-2013-0111703 filed on Sep. 17, 2013, with the Korean Intellectual Property Office, the disclosure of which is incorporated herein by reference.

### BACKGROUND

The present disclosure relates to a microphone using a piezoelectric element, and more particularly, to a microphone, a sensitivity of which to sound waves is adjustable.

A microphone is a device converting sound waves into electrical signals. A microphone includes a thin film member receiving sound waves and a converting unit converting vibrations of the thin film member into electrical signals.

Microphones may be divided into capacitive type microphones and piezoelectric type microphones, depending on the method of sensing sound waves utilized thereby. The former converts sound waves into electrical signals through changes in capacitance, due to the vibrations of the thin film member, and the latter senses sound waves by electrical signals of a piezoelectric element generated by the vibrations of the thin film member.

Here, since the piezoelectric type microphone has a structure in which the piezoelectric element is formed on one surface of the thin film member, it may be relatively simply manufactured and has a relatively simple structure, such that it is advantageous for miniaturization. However, the piezoelectric element is formed on one surface of the thin film member as described above to hinder vibrations or warpage deformation of the thin film member, thereby decreasing sensitivity thereof to sound waves.

Therefore, development of a microphone capable of improving sensitivity to sound waves in spite of having a piezoelectric type structure has been demanded. For reference, as the related art as sociated with the present disclosure, there are provided Patent Documents 1 and 2.

### RELATED ART DOCUMENT

(Patent Document 1) U.S. Pat. No. 5,856,956 A1
(Patent Document 2) U.S. Pat. No. 7,615,912 B2

### SUMMARY

An aspect of the present disclosure may provide a piezoelectric type microphone capable of adjusting and improving sensitivity to sound waves.

According to an aspect of the present disclosure, a microphone may include: a thin film member including leg members extended in a direction not in parallel with a vibration direction; first supports supporting first points of the leg members, respectively; and a piezoelectric member connected to second points of the leg members and converting vibrations of the thin film member into electrical signals.

The thin film member may be more adjacent to the first point than the second point.

A plurality of leg members may be provided and may be disposed in a rotation symmetrical form based on the center of the thin film member.

The piezoelectric member may include: a first piezoelectric member extended from one end of the leg member toward a fixed body; and a second piezoelectric member extended from the other end of the leg member toward the fixed body.

A distance from a connection point between the first piezoelectric member and the leg member to the first point may be different from a distance from a connection point between the second piezoelectric member and the leg member to the second point.

The piezoelectric member may be disposed so that both ends thereof are connected to a fixed body based on the leg member.

The piezoelectric member may be disposed so that both ends thereof are connected to the first support based on the leg member.

The piezoelectric member may have a curved shape.

The first support may have a curved shape.

The piezoelectric member may include: a first piezoelectric member connected to the second point on the leg member; and a second piezoelectric member connected to a third point on the leg member.

A distance from the first point to the second point may be different from a distance from a connection point between the leg member and the thin film member to the first point.

According to another aspect of the present disclosure, a microphone may include: a thin film member including a plurality of leg members extended in a direction not in parallel with a vibration direction; first supports supporting first points of the plurality of leg members, respectively; second supports connecting the first supports and a fixed body to each other, respectively; and a piezoelectric member connected to second points of the leg members and the second supports and converting vibrations of the thin film member into electrical signals.

The thin film member may have a circular shape, and the first support may have a ring shape.

The piezoelectric member may have a ring shape in which it encloses the outside of the thin film member.

The piezoelectric member may include: a first piezoelectric member connecting the second point on the leg member and the second support to each other; and a second piezoelectric member connecting a third point on the leg member and the second support to each other.

The first and second piezoelectric members may have a curved shape, and the first piezoelectric member may have a radius of curvature larger than that of the second piezoelectric member.

A distance from the first point to the second point may be equal to or different from a distance from a connection point between the leg member and the thin film member to the first point.

According to another aspect of the present disclosure, a microphone may include: a thin film member connected to a fixed body by at least two leg members; and a piezoelectric member connected to the fixed body and the leg members and converting vibrations of the thin film member into electrical signals.

The thin film member may have a circular or oval shape, and the piezoelectric member may have a curved shape in which it is extended lengthwise along a circumference of the thin film member.

Both ends of the piezoelectric member may be disposed to be connected to different leg members, respectively.

The piezoelectric member may include: a first piezoelectric member connected to a first point on the leg member; and a second piezoelectric member connected to a second point on the leg member.

The microphone may further include a protrusion member extended from the fixed body and connected to the piezoelectric member.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a view showing a configuration of a microphone according to an exemplary embodiment of the present disclosure;

FIG. 2 is an enlarged view of part A shown in FIG. 1;

FIG. 3 is a cross-sectional view taken along line B-B of FIG. 1;

FIG. 4 is a cross-sectional view taken along line B-B for describing an operational principle of the microphone shown in FIG. 1;

FIGS. 5 through 10 are plan views another form of the microphone shown in FIG. 1;

FIG. 11 is a view showing a configuration of a microphone according to another exemplary embodiment of the present disclosure;

FIG. 12 is a perspective view showing a part of the microphone shown in FIG. 11;

FIGS. 13 and 14 are plan views showing another form of the microphone shown in FIG. 11;

FIG. 15 is a view showing a configuration of a microphone according to another exemplary embodiment of the present disclosure;

FIG. 16 is a cross-sectional view taken along line C-C of FIG. 15;

FIGS. 17 and 18 are plan views showing another form of the microphone shown in FIG. 15; and

FIG. 19 is a plan view showing another form of the microphone shown in FIG. 15.

### DETAILED DESCRIPTION

Exemplary embodiments of the present disclosure will now be described in detail with reference to the accompanying drawings.

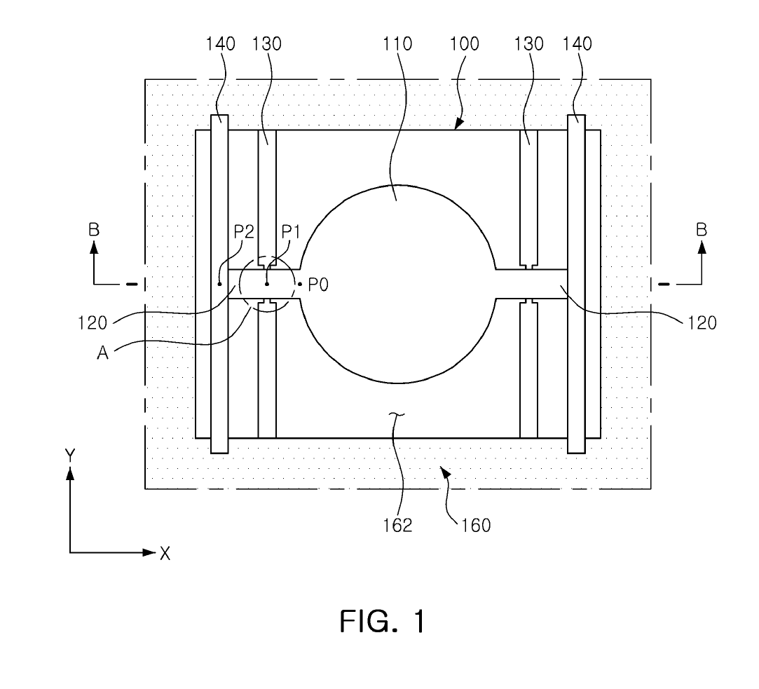

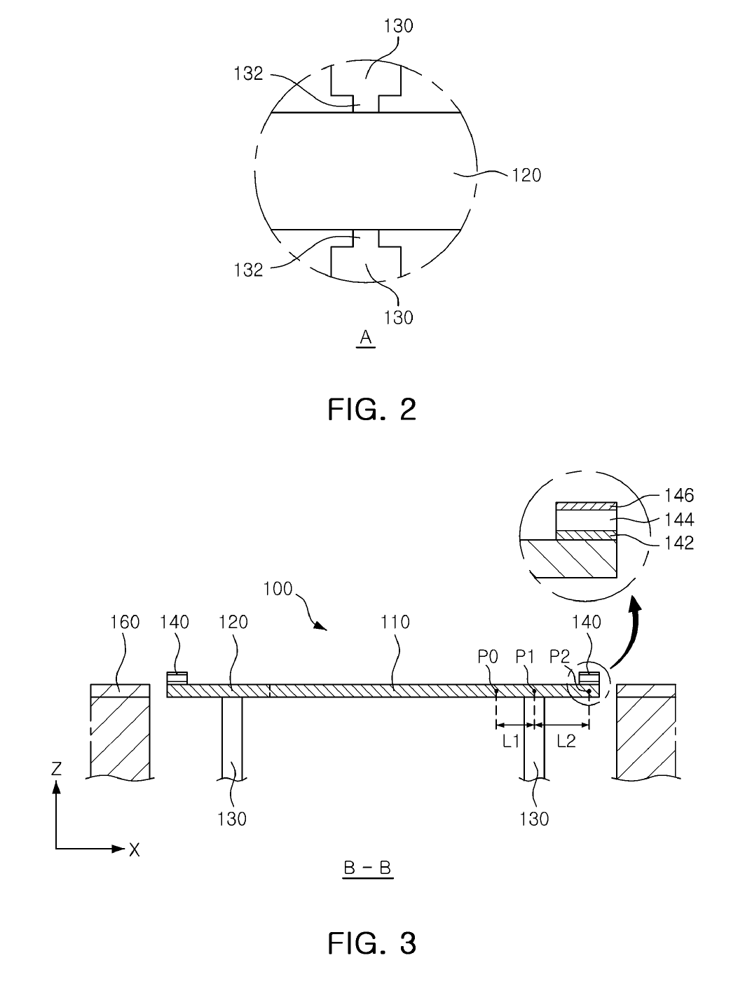

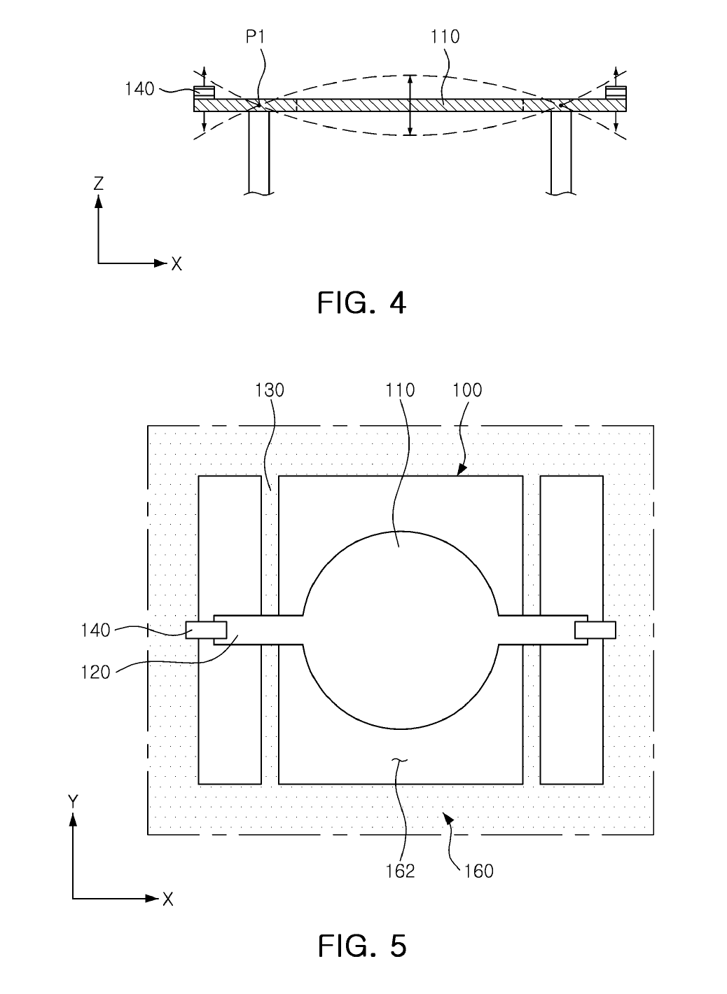

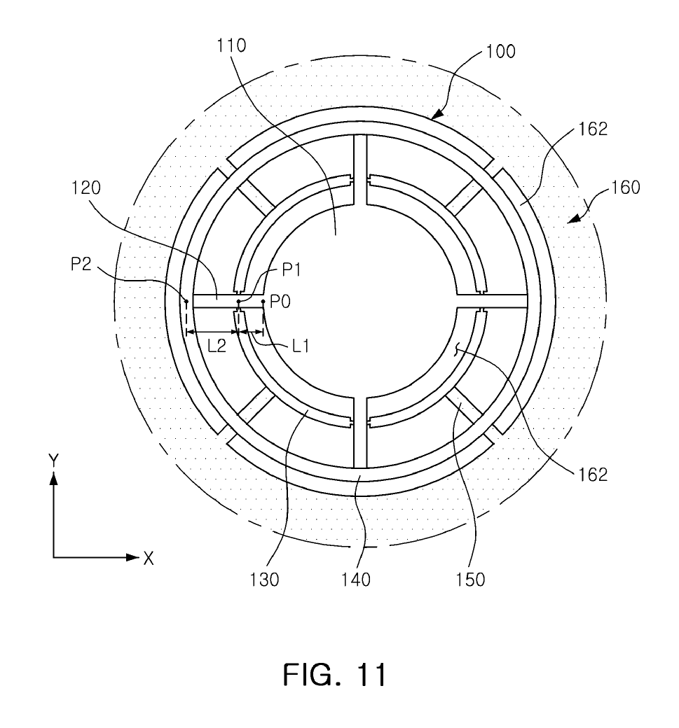

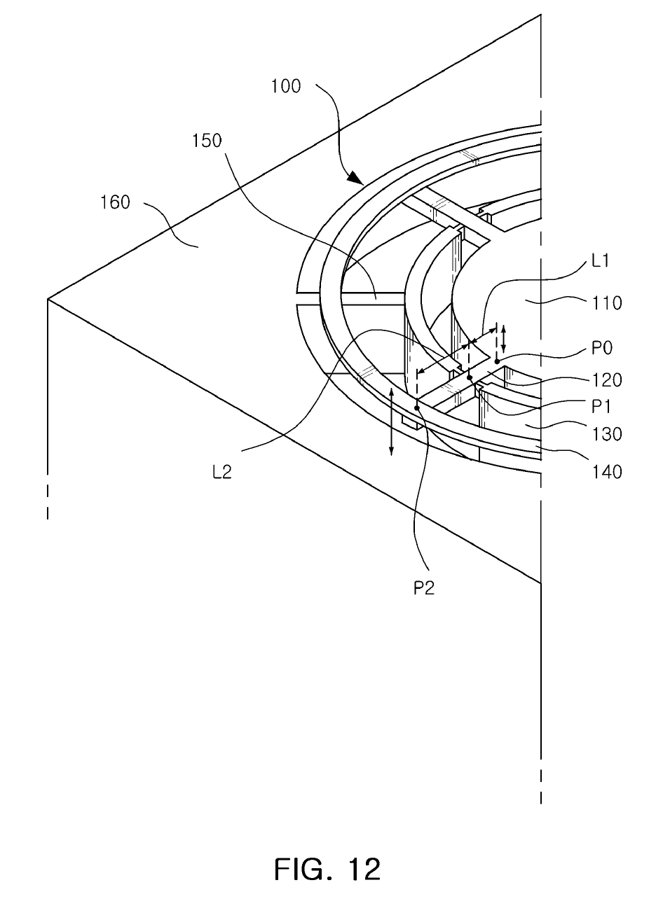

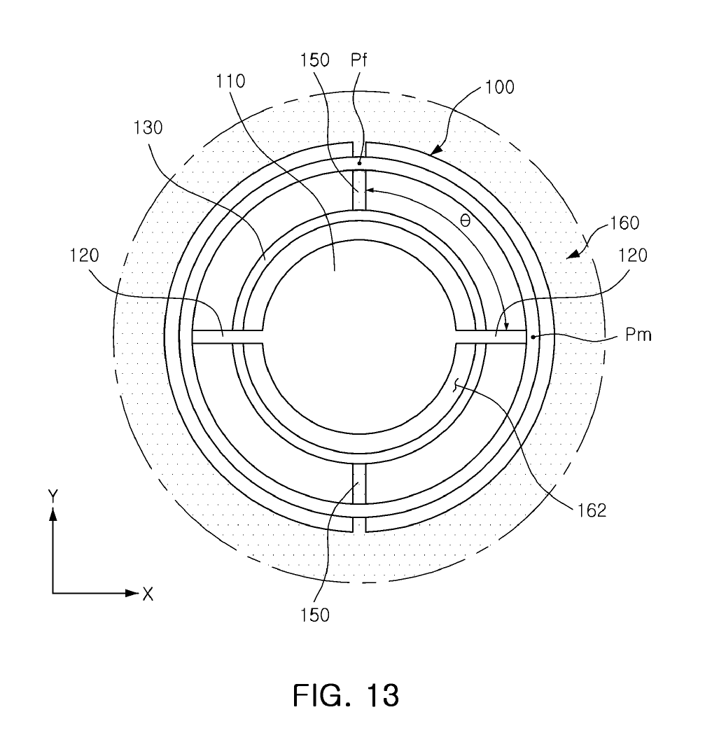

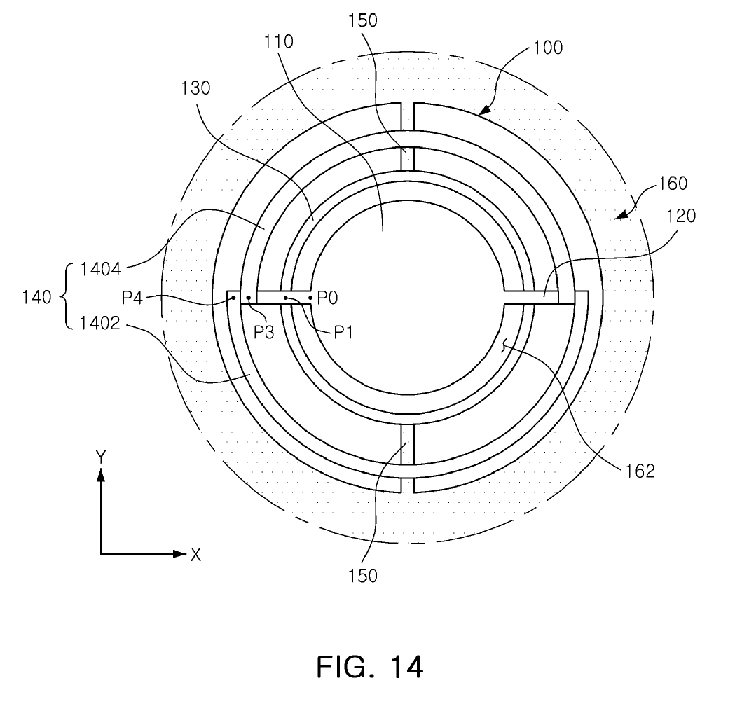

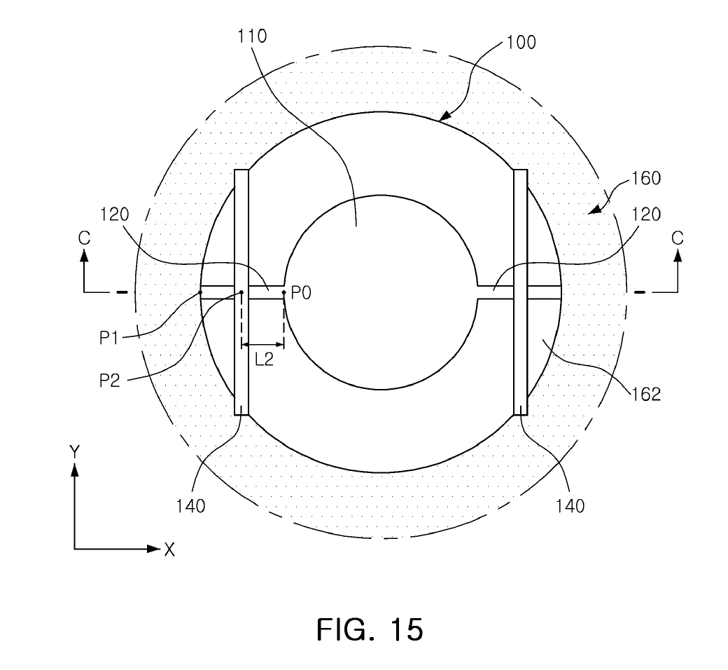

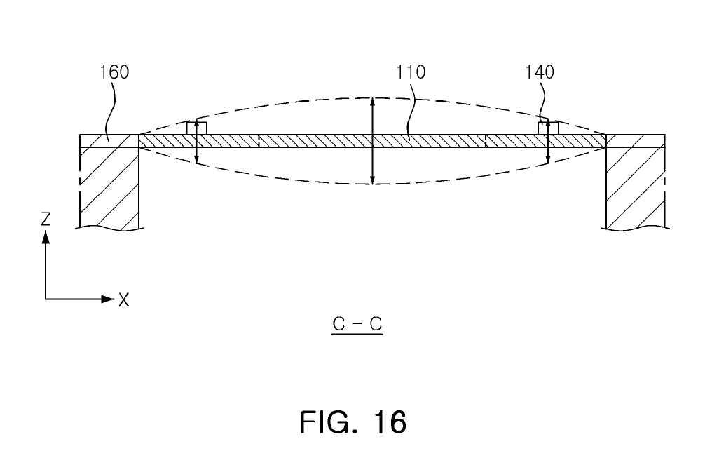

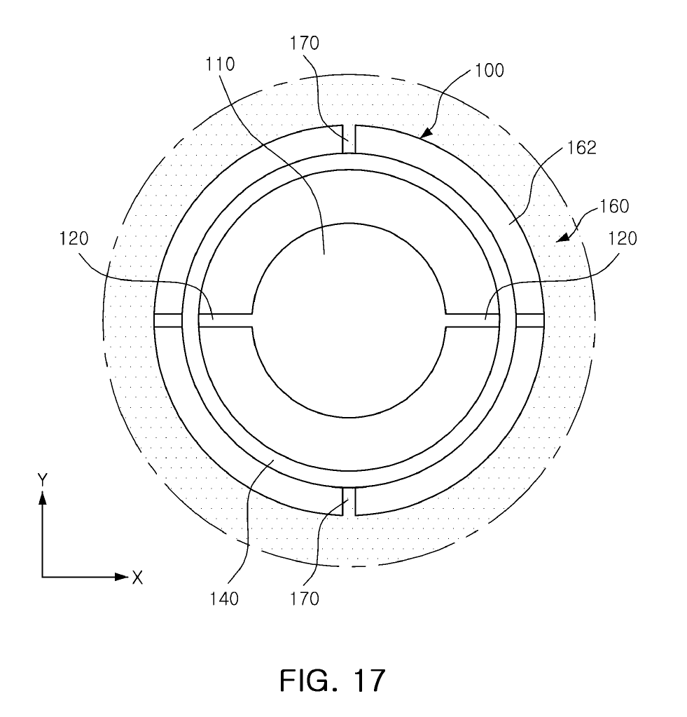

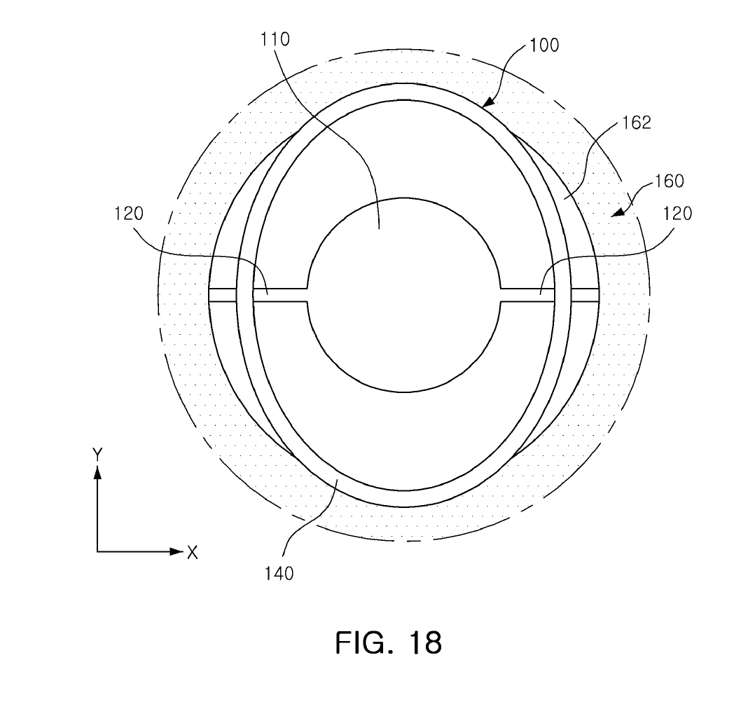

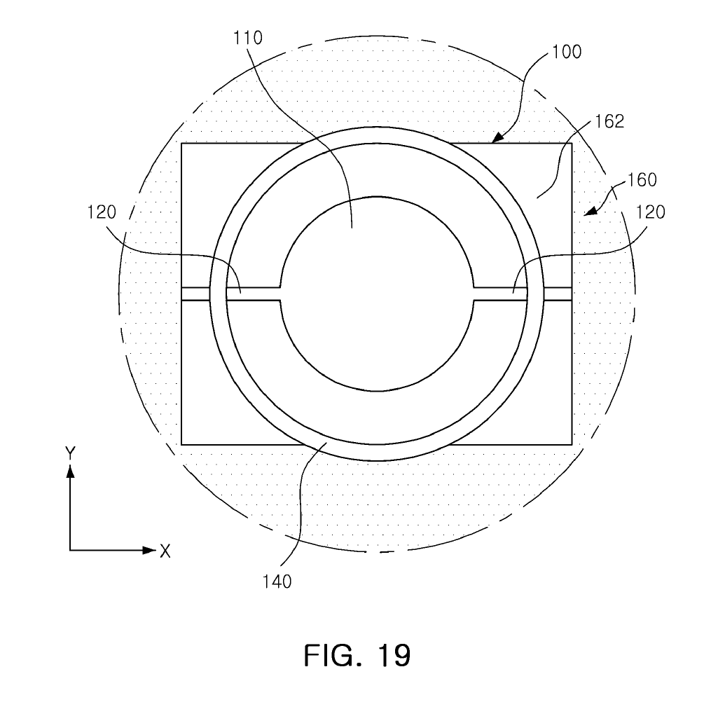

FIG. 1 is a view showing a configuration of a microphone according to an exemplary embodiment of the present disclosure; FIG. 2 is an enlarged view of part A shown in FIG. 1; FIG. 3 is a cross-sectional view taken along line B-B of FIG. 1; FIG. 4 is a cross-sectional view taken along line B-B for describing an operational principle of the microphone shown in FIG. 1; FIGS. 5 through 10 are plan views another form of the microphone shown in FIG. 1; FIG. 11 is a view showing a configuration of a microphone according to another exemplary embodiment of the present disclosure; FIG. 12 is a perspective view showing apart of the microphone shown in FIG. 11; FIGS. 13 and 14 are plan views showing another form of the microphone shown in FIG. 11; FIG. 15 is a view showing a configuration of a microphone according to another exemplary embodiment of the present disclosure; FIG. 16 is a cross-sectional view taken along line C-C of FIG. 15; FIGS. 17 and 18 are plan views showing another form of the microphone shown in FIG. 15; and FIG. 19 is a plan view showing another form of the microphone shown in FIG. 15.

A microphone according to an exemplary embodiment of the present disclosure will be described with reference to FIGS. 1 through 4.

The microphone 100 according to the exemplary embodiment of the present disclosure may include a thin film member 110, leg members 120, first supports 130, and piezoelectric members 140. In addition, the microphone 100 may include a fixed body 160 configuring an outer casing of the microphone 100.

The microphone 100 configured as described above may be mounted in a portable terminal or other electronic devices and convert sound waves into electrical signals.

Hereinafter, detailed components of the microphone 100 will be described.

The thin film member 110 may be vibrated by sound waves. For example, the thin film member 110 may have a film form. The thin film member 110 may be formed of a silicon dioxide (SiO₂) film, a silicon nitride film, or the like, deposited on one surface of the fixed body 160. More specifically, the thin film member 110 may be formed by depositing the silicon dioxide (SiO₂) film or the silicon nitride film on a silicon substrate and then etching the silicon substrate.

The thin film member 110 may have a circular shape. However, the thin film member 110 is not limited to having the circular shape, but may have other shapes such as a square shape or a regular polygonal shape if necessary.

The thin film member 100 may include a plurality of layers. For example, the thin film member 110 may include a first layer formed of a silicon dioxide or silicon nitride film and a second layer formed of a dielectric material on the first layer. Here, the second layer may be used as a lower electrode layer of the piezoelectric member 140.

The leg members 120 may be formed on the thin film member 110 and be extended lengthwise in a plane direction of the thin film member 110. More specifically, a plurality of leg members 120 may be extended in a rotation symmetrical form based on the center of gravity of the thin film member 110.

The leg member 120 may be formed integrally with the thin film member 110. More specifically, the leg member 120 may be formed of a silicon dioxide (SiO₂) film, a silicon nitride film, or the like, similar to the thin film member 110.

The first supports 130 may be formed in the fixed body 160. More specifically, the first supports 130 may be formed together with the fixed body 160 in a process of forming a sound wave inlet 162 in the fixed body 160. The first supports 130 may be a part of the fixed body 160.

The first supports 130 may support the leg members 120. More specifically, the first support 130 may rotate freely, based on a connection point P1 (See FIG. 3) (hereinafter, referred to as a first point) between the leg member 120 and the first support 130. Therefore, when sound waves are introduced through the sound wave inlet 162, the thin film member 110 may vibrate in a vertical direction (a Z axis direction in FIG. 4) as illustrated with a dotted line in FIG. 4.

The first support 130 may include a pair of protrusions 132 as shown in FIG. 2. The pair of protrusions 132 may contact both sides of the leg member 120 as shown in FIG. 2 to enable smooth movement of the leg member 120.

The piezoelectric element 140 may connect the leg member 120 and the fixed body 160 to each other. More specifically, the piezoelectric member 140 may be extended from the fixed body 160 to the leg member 120.

The piezoelectric member 140 may convert vibrations of the thin film member 110 into electrical signals. More specifically, a portion of the piezoelectric member 140 formed in the fixed body 160 may be firmly fixed, such that it does not move. However, a portion of the piezoelectric member 140 extended to the leg member 120 may be bent in the Z axis direction (See FIG. 4) depending on movement of the leg member 120. The piezoelectric member 140 is bent as described above to generate a piezoelectric effect, whereby a current having a predetermined magnitude may be generated. That is, when the leg member 120 moves vertically due to the vibrations of the thin film member 110, the piezoelectric member 140 may generate the current having the predetermined magnitude whenever the leg member 120 moves. Here, since the magnitude of the current is in proportion to an amplitude of the leg member 120, the piezoelectric member 140 may transmit current signals having different magnitudes, depending on a vibration frequency of the thin film member 110 to a controlling unit.

A position of the piezoelectric member 140 may be arbitrarily set. More specifically, since the amplitude of the leg member 120 increases from the first point P1 toward the outside (toward the fixed body 160 in FIG. 3), sensitivity to sound waves of the piezoelectric member 140 may be adjusted by adjusting a position of a connection point P2 (hereinafter, referred to as a second point) between the piezoelectric member 140 and the leg member 120. For example, when a distance L2 from the first point P1 to the second point P2 is shorter than a distance L1 from a connection point P0 (hereinafter, referred to as a comparison point) between the thin film member 110 and the leg member 120 to the first point P1, sensitivity to sound waves may be decreased. On the contrary, when the distance L2 is greater than the distance L1, sensitivity to sound waves may be increased.

The piezoelectric member 140 may include a lower electrode 142, a piezoelectric element 144, and an upper electrode 146, as shown in FIG. 3. The lower electrode 142 may be formed on the fixed body 160. More specifically, the lower electrode 142 may be formed over one surface of the fixed body 160 via an adhesive such as epoxy. The lower electrode 142 may be made of a conductive material. The lower electrode may be formed of two metal thin film layers made of titanium (Ti) and platinum (Pt), respectively. The piezoelectric element 144 may be formed of a piezoelectric material. For example, the piezoelectric element 144 may be formed of a ceramic, more specifically, lead zirconate titanate (PZT). The piezoelectric element 144 configured as described above may generate a predetermined electrical signal while being contracted or released depending on the amplitude of the leg member 120. Here, the electrical signal may be changed depending on the amplitude of the leg member 120 and a size and a length of the piezoelectric element 144. The upper electrode 146 may be formed on an upper surface of the piezoelectric element 144. The upper electrode 146 may be formed of any one material selected from a group consisting of Pt, Au, Ag, Ni, Ti, Cu, and the like. Here, the lower electrode 142 and the upper electrode 146 may be connected to external circuits to transmit the electrical signal generated from the piezoelectric element 144 to an electronic device in which the microphone 100 is mounted.

The fixed body 160 may form an outer casing of the microphone 100 and be formed of one or more substrate. More specifically, the fixed body 160 may be formed in an array form on a single crystal silicon substrate or a silicon on insulator (SOI) substrate through a semiconductor process. The fixed body 160 manufactured in the scheme as described above may have a rectangular, polygonal, or circular cross section by a cutting process.

The fixed body 160 may be provided with the sound wave inlet 162 through which sound waves are introduced. The sound wave inlet 162 may be formed by an etching process of a silicon substrate. For reference, the etching process may include both dry and wet etching processes. Meanwhile, although the case in which a cross section of the sound wave inlet 162 has a rectangular shape has been shown in the accompanying drawings, the cross section of the sound wave inlet 162 is not limited to the rectangular shape, and the cross section of the sound wave inlet 162 may have a circular shape or other shapes if necessary.

Since the microphone 100 configured as described above may effectively sense the vibrations of the thin film member 110 while preventing the piezoelectric member 140 from hindering the vibrations of the thin film member 110, it may improve sensitivity to sound waves.

In addition, since the microphone 100 according to the exemplary embodiment of the present disclosure may adjust sensitivity to sound waves by adjusting the connection point (that is, the second point P2) between the piezoelectric member 140 and the leg member 120, it may be applied to various fields.

Next, another form of the microphone according to the exemplary embodiment of the present disclosure will be described with reference to FIGS. 5 through 10.

In another form of the microphone 100, a disposition form of the piezoelectric member 140 may be changed, as shown in FIG. 5. More specifically, the piezoelectric member 140 may be extended in a direction in which it is in parallel with the leg member 120. Here, the piezoelectric member 140 may have one end fixed to the fixed body 160 and the other end connected to the leg member 120.

The microphone 100, configured as described above, may have an advantage that a length of the piezoelectric member 140 may be decreased.

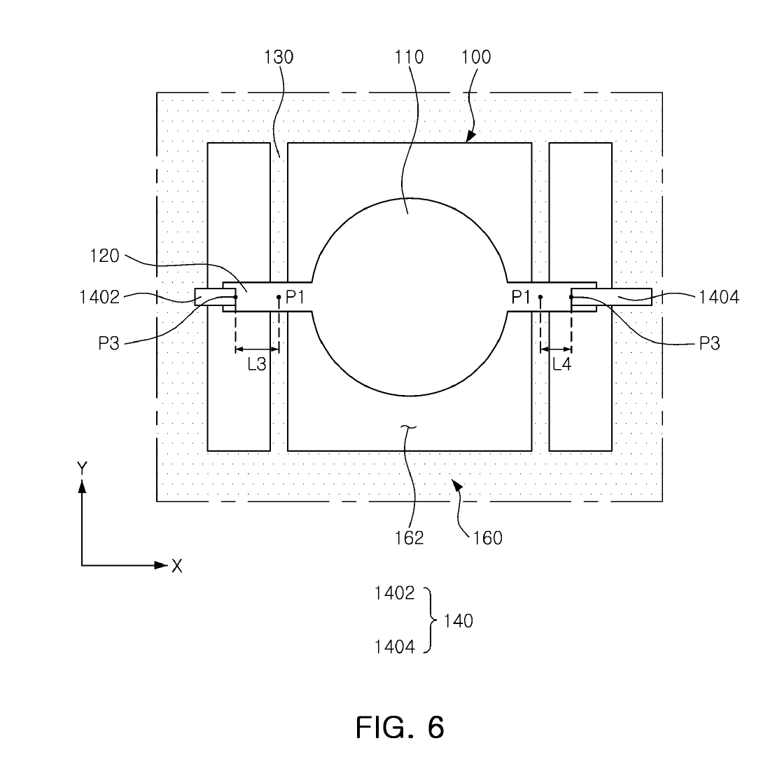

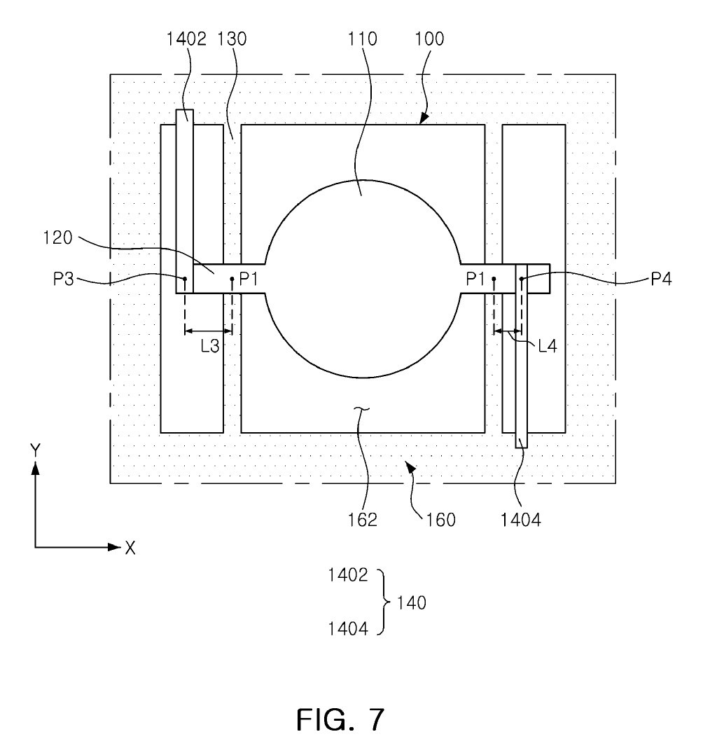

Another form of the microphone 100 may include piezoelectric members 140: 1402 and 1404 having different shapes as shown in FIGS. 6 and 7. More specifically, first and second piezoelectric members 1402 and 1404 may have different sizes and be connected to the leg members 120 at different points P3 and P4, respectively. More specifically, the first piezoelectric member 1402 may be connected to the leg member 120 at a third point P3, and the second piezoelectric member 1404 may be connected to the leg member 120 at a fourth point P4. Here, a distance L3 from the first point P1 to the third point P3 may be longer than a distance L4 from the first point P1 to the fourth point P4.

In the microphone configured as described above, since two piezoelectric members 1402 and 1404 sense sound waves at different sensitivities, sound waves may be simultaneously sensed in various bands.

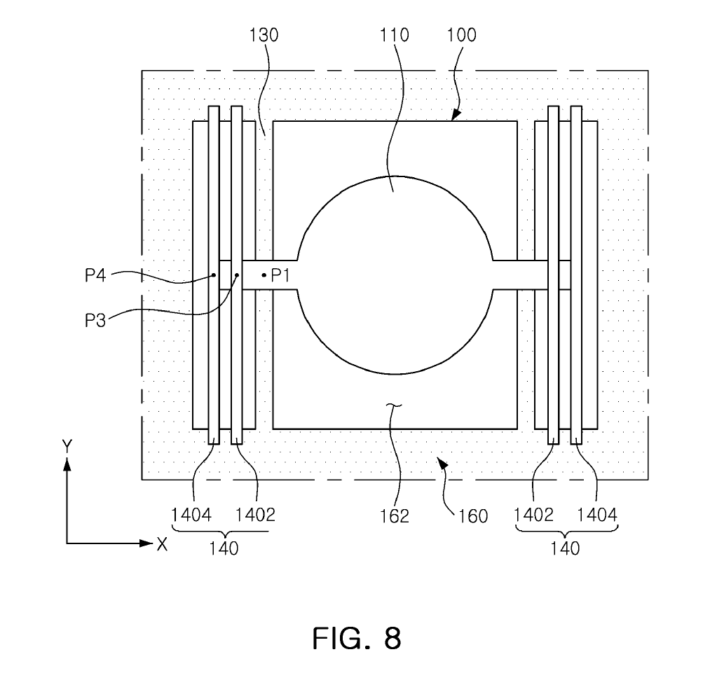

In another form of the microphone, a plurality of piezoelectric members 140: 1402 and 1404 may be disposed in parallel with each other as shown in FIG. 8. As a result, sensitivity to sound waves may be further improved.

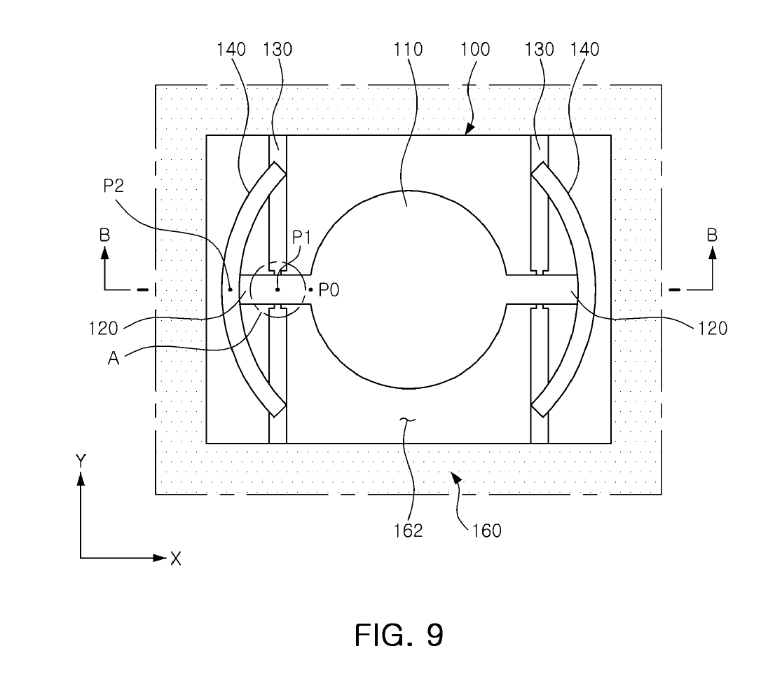

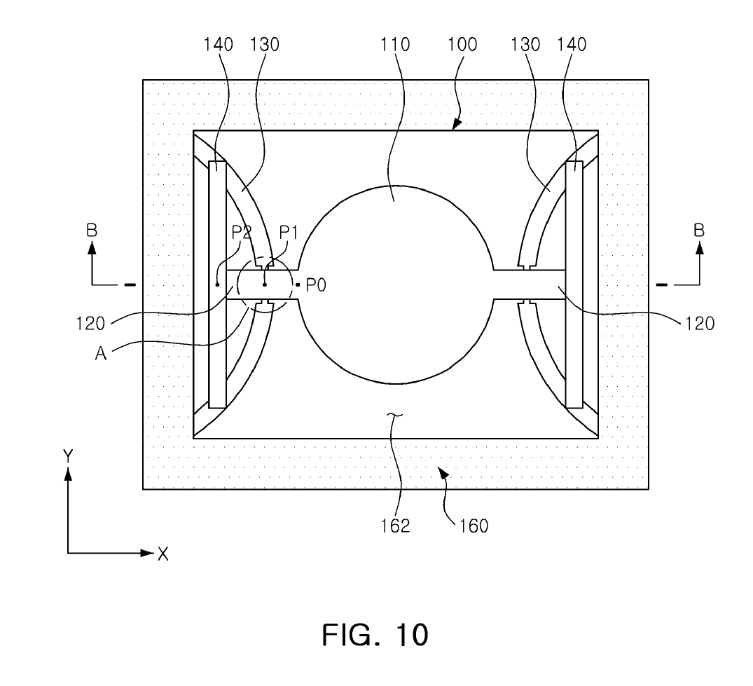

Another form of the microphone may be different in terms of a manner in which the piezoelectric member 140 is disposed from the form of the microphone described above, as shown in FIGS. 9 and 10. More specifically, in the present form, the piezoelectric member 140 may be connected to the first support 130. To this end, a shape of the piezoelectric member 140 may be changed to a curved shape as shown in FIG. 9. Alternatively, a shape of the first support 130 may be changed to a curved shape as shown in FIG. 10.

Next, a microphone according to another exemplary embodiment of the present disclosure will be described. For reference, in the following description, the same components as those of the microphone according to the exemplary embodiment of the present disclosure described above will be denoted by the same reference numerals and a description thereof will be omitted.

A microphone according to another exemplary embodiment of the present disclosure will be described with reference to FIGS. 11 and 12.

The microphone 100 according to another exemplary embodiment of the present disclosure may include a thin film member 110, leg members 120, first supports 130, apiezoelectric member 140, and second supports 150, and may be different from the microphone 100 according to the exemplary embodiment of the present disclosure described above in terms of a disposition structure of the piezoelectric member 140.

The thin film member 110 may have a circular cross section and include a plurality of leg members 120. The leg members 120 may be extended in a radial direction based on the center of gravity of the thin film member 110 and be connected to the first supports 130. Here, a connection structure between the leg member 120 and the first support 130 may be the same as or similar to the connection structure between the leg member 120 and the first support 130 in the exemplary embodiment of the present disclosure described above. Therefore, seesaw movement in which the other end (portion connected to the piezoelectric member 140) of the leg member 120 vibrates in a direction opposite to one direction when one end (portion connected to the thin film member 110) of the leg member 120 vibrates in one direction may be performed.

The piezoelectric member 140 may have a ring shape. More specifically, the piezoelectric member 140 may have a closed curved shape in which it encloses a circumference of the thin film member 10. However, the piezoelectric member 140 is not limited to having the ring shape, but may have a curved shape in which a portion thereof is opened if necessary.

The piezoelectric member 140 may be disposed so that a distance L2 from the first point P1 to the second point P2 is greater than a distance L1 from the comparison point P0 to the first point P1. This disposition structure may be advantageous for transferring fine vibrations of the thin film member 110 to the piezoelectric member 140.

The second supports 150 may be radially extended from the fixed body 160 toward the center of the thin film member 110. Here, the number of second supports 150 may be the same as that of leg members 120, and the second supports 150 may be disposed so as not to be overlapped with the leg members 120. The second supports 150 formed as described above may be connected to the first supports 130 to fix the first supports 130 to the fixed body 160. In addition, the second supports 150 may fix a part of the piezoelectric member 140.

In the microphone 100, configured as described above, since the piezoelectric member 140 having the ring shape is connected to the plurality of leg members 120 to sense the vibrations of the thin film member 110, sensitivity to sound waves may be improved.

Next, another form of the microphone according to another exemplary embodiment of the present disclosure will be described with reference to FIGS. 13 and 14.

In another form of the microphone according to another exemplary embodiment of the present disclosure, as shown in FIG. 13, the numbers of leg members 120 and second supports 150 may be decreased. More specifically, in the present form, the numbers of leg members 120 and second supports 150 may be two, respectively. In this form, since an angle θ from a fixed position Pf of the piezoelectric member 140 to a movable point Pm of the piezoelectric member 140 is increased, an extension and contraction rate of the piezoelectric member 140 may be increased. As a result, sensitivity to sound waves may be improved.

Another form of the microphone may include a plurality of piezoelectric members 140: 1402 and 1404 as shown in FIG. 14. Here, the respective piezoelectric members 140: 1402 and 1404 may sense sound waves in different frequency bands.

To this end, a first piezoelectric member 1402 may be connected to the leg member 120 at a fourth point P4, and a second piezoelectric member 1404 may be connected to the leg member 120 at a third point P3. Here, since the first piezoelectric member 1402 has a displacement width relatively larger than that of the second piezoelectric member 1404, it may sense sound waves in a high frequency band. Unlike this, since the second piezoelectric member 1404 has a displacement width relatively smaller than that of the first piezoelectric member 1402, it may sense sound waves in a low frequency band.

A microphone according to another exemplary embodiment of the present disclosure will be described with reference to FIGS. 15 and 18.

The microphone 100 according to another exemplary embodiment of the present disclosure may be different in terms of a connection structure of a leg member 120 from the microphones 100 according to the exemplary embodiments of the present disclosure described above. That is, in the microphone 100 according to another exemplary embodiment of the present disclosure, the leg member 120 may be directly connected to the fixed body 160 without a separate support. In addition, the piezoelectric member 140 may be extended from the fixed body 160 toward the leg member 120 and connected to a second point P2 of the leg member 120.

In the microphone 110 configured as described above, an amplitude of the leg member 120 depending on vibrations of the thin film member 110 may be reduced from a comparison point P0 to a first point P1, as shown in FIG. 16. Therefore, a position of the second point P2 at which the piezoelectric member 140 and the leg member 120 are connected to each other is adjusted, whereby sensitivity to sound waves may be raised or lowered. For example, when a length L2 from the second point P2 to the comparison point P0 is reduced, the vibrations of the thin film member 110 are transferred well to the piezoelectric member 140, whereby sensitivity to sound waves may be raised. Unlike this, when the length L2 is increased, the vibrations of the thin film member 110 are not properly transferred to the piezoelectric member 140, whereby sensitivity to sound waves may be lowered. However, when the distance L2 is excessively short, the piezoelectric member 140 may hinder the vibrations of the thin film member 110. Therefore, it may be preferable that the second point P2 be spaced apart from the comparison point P0 by a predetermined distance.

Meanwhile, in another form of the microphone 100, the piezoelectric member 140 may have a ring shape having an oval trajectory (See FIG. 17). In addition, in another form of the microphone 100, the piezoelectric member 140 may have a ring shape having a circular trajectory, and the sound wave inlet 162 may have a rectangular cross-sectional shape (See FIG. 18).

Since the microphone 100 configured as described above may have a simplified structure, a process of manufacturing the microphone 100 may be simplified and a cost required to manufacture the microphone 100 may be decreased.

Next, another form of the microphone according to another exemplary embodiment of the present disclosure will be described with reference to FIG. 19.

Another form of the microphone 100 may include a protrusion member 170 and have a form similar to the form shown in FIG. 11. That is, in another exemplary embodiment of the present disclosure, the piezoelectric member 140 may be fixed to the protrusion member 170 and have a ring shape.

As set forth above, since the microphone according to the exemplary embodiments of the present disclosure may arbitrarily adjust sensitivity to sound waves, it may be widely used from a precision field requiring a high sensitivity to a general field requiring a low sensitivity.

In addition, since the microphone according to the exemplary embodiments of the present disclosure may convert the vibrations of the thin film member into the electrical signal of the piezoelectric element, sensitivity to sound waves may be improved.

While exemplary embodiments have been shown and described above, it will be apparent to those skilled in the art that modifications and variations could be made without departing from the spirit and scope of the present disclosure as defined by the appended claims.

What is claimed is:

1. A microphone comprising:
a thin film member including leg members extended in a direction not in parallel with a vibration direction;
first supports supporting first points of the leg members, respectively; and
a piezoelectric member connected to second points of the leg members and converting vibrations of the thin film member into electrical signals.

2. The microphone of claim 1, wherein the thin film member is more adjacent to the first point than the second point.

3. The microphone of claim 1, wherein a plurality of leg members are provided and are disposed in a rotation symmetrical form based on the center of the thin film member.

4. The microphone of claim 1, wherein the piezoelectric member includes:
a first piezoelectric member extended from one end of the leg member toward a fixed body; and
a second piezoelectric member extended from the other end of the leg member toward the fixed body

5. The microphone of claim 4, wherein a distance from a connection point between the first piezoelectric member and the leg member to the first point is different from a distance from a connection point between the second piezoelectric member and the leg member to the second point.

6. The microphone of claim 1, wherein the piezoelectric member is disposed so that both ends thereof are connected to a fixed body based on the leg member.

7. The microphone of claim 1, wherein the piezoelectric member is disposed so that both ends thereof are connected to the first support based on the leg member.

8. The microphone of claim 7, wherein the piezoelectric member has a curved shape.

9. The microphone of claim 7, wherein the first support has a curved shape.

10. The microphone of claim 1, wherein the piezoelectric member includes:
a first piezoelectric member connected to the second point on the leg member; and
a second piezoelectric member connected to a third point on the leg member.

11. The microphone of claim 1, wherein a distance from the first point to the second point is different from a distance from a connection point between the leg member and the thin film member to the first point.

12. A microphone comprising:
a thin film member including a plurality of leg members extended in a direction not in parallel with a vibration direction;
first supports supporting first points of the plurality of leg members, respectively;
second supports connecting the first supports and a fixed body to each other, respectively; and
a piezoelectric member connected to second points of the leg members and the second supports and converting vibrations of the thin film member into electrical signals.

13. The microphone of claim 12, wherein the thin film member has a circular shape, and
the first support has a ring shape.

14. The microphone of claim 13, wherein the piezoelectric member has a ring shape in which it encloses the outside of the thin film member.

15. The microphone of claim 13, wherein the piezoelectric member includes:
a first piezoelectric member connecting the second point on the leg member and the second support to each other; and
a second piezoelectric member connecting a third point on the leg member and the second support to each other.

16. The microphone of claim 15, wherein the first and second piezoelectric members have a curved shape, and
the first piezoelectric member has a radius of curvature larger than that of the second piezoelectric member.

17. The microphone of claim 13, wherein a distance from the first point to the second point is equal to or different from a distance from a connection point between the leg member and the thin film member to the first point.

18. A microphone comprising:
a thin film member connected to a fixed body by at least two leg members; and
a piezoelectric member connected to the fixed body and the leg members and converting vibrations of the thin film member into electrical signals.

19. The microphone of claim 18, wherein the thin film member has a circular or oval shape, and
the piezoelectric member has a curved shape in which it is extended lengthwise along a circumference of the thin film member.

20. The microphone of claim 18, wherein both ends of the piezoelectric member are disposed to be connected to different leg members, respectively.

21. The microphone of claim 18, wherein the piezoelectric member includes:
a first piezoelectric member connected to a first point on the leg member; and
a second piezoelectric member connected to a second point on the leg member.

22. The microphone of claim 18, further comprising a protrusion member extended from the fixed body and connected to the piezoelectric member.
